(19) United States
(12) Patent Application Publication
(10) Pub. No.: US 2026/0235906 A1
(43) Pub. Date: Aug. 13, 2026

(54) BACKLIGHT AND GESTURE DETECTION DEVICE

(71) Applicant: Commissariat à l'Énergie Atomique et aux Énergies Alternatives, Paris (FR)

(72) Inventors: François Templier, Grenoble (FR); Sylvain Maitrejean, Grenoble (FR)

(73) Assignee: Commissariat à l'Énergie Atomique et aux Énergies Alternatives, Paris (FR)

(21) Appl. No.: 19/468,644

(22) Filed: Feb. 3, 2026

(30) Foreign Application Priority Data
Feb. 7, 2025 (FR) FR2501292

(51) Int. Cl. G02F 1/13357; G02F 1/1333; G02F 1/1335; G06F 3/01; H10F 39/18; H10F 55/00; H10F 77/124; H10H 29/01; H10H 29/14; H10H 29/24; H10H 29/851

(52) U.S. Cl. CPC G02F 1/133603; G02F 1/13338; G02F 1/133609; G06F 3/017; H10F 39/1843; H10F 55/00; H10F 77/1248; H10H 29/011; H10H 29/0361; H10H 29/14; H10H 29/24; H10H 29/8514; G02F 1/133528

(57) ABSTRACT

A backlight and gesture detection device including: first elements for emitting white light; second elements for emitting infrared radiation or visible light; and third elements for detecting infrared radiation or visible light emitted by the second elements, wherein the first, second and third elements are electrically connected to a same substrate.

### TECHNICAL FIELD

The present disclosure generally relates to electronic devices, and more specifically display devices integrating a gesture detection function.

### Background Art

Display devices integrating a gesture detection function, such as the liquid crystal display (LCD) screen with multiple functions known under the trade name “IRIS” from the company Embodme and described in the article by E. Hemery and E. Santoul entitled “IRIS: Integrating 3D Sensing with LCD Screens for Enhanced Touch Interaction,” have been proposed. This screen comprises a liquid crystal matrix backlit by light-emitting diodes (LEDs) located either on the perimeter (edge-lit technology) of or in line with (back-lit technology) the liquid crystal matrix. The screen also integrates a gesture detection device comprising an array of infrared photo-emitters and photodetectors. In this screen, the backlight LEDs and the array of infrared photo-emitters and photodetectors are formed on distinct substrates.

The existing display devices integrating a gesture detection function and the methods for manufacturing such devices have various disadvantages.

### SUMMARY OF THE INVENTION

There is a need to overcome all or part of the disadvantages of the existing display devices integrating a gesture detection function and of the methods for manufacturing such devices.

To this end, one embodiment provides a backlight and gesture detection device comprising:
first elements for emitting white light;
second elements for emitting infrared radiation or visible light; and
third elements for detecting infrared radiation or visible light emitted by the second elements, wherein the first, second and third elements are electrically connected to a same substrate, the device comprising a plurality of elementary chips, each comprising one or more elements among one of the first elements, one of the second elements and one of the third elements.

According to one embodiment, the device comprises a plurality of elementary chips, each comprising one of the first elements, one of the second elements and one of the third elements.

According to one embodiment, each elementary chip further comprises an elementary circuit for controlling the first, second and third elements.

According to one embodiment, the device comprises:
a plurality of first elementary chips, each comprising one of the first elements and one of the second elements; and
a plurality of second elementary chips, each comprising one of the third elements.

According to one embodiment, each first elementary chip further comprises an elementary circuit for controlling the first, second and third elements.

According to one embodiment, each third element is an infrared photodetector based on indium gallium arsenide.

According to one embodiment, the device comprises:
a plurality of first elementary chips, each comprising one of the first elements; and
a plurality of second elementary chips, each comprising one of the second elements and one of the third elements.

According to one embodiment, each first elementary chip further comprises an elementary circuit for controlling the first, second and third elements.

According to one embodiment, each first element comprises a first light-emitting diode topped with a first color converter.

According to one embodiment, each second element comprises a second light-emitting diode topped with a second visible-to-infrared converter.

According to one embodiment, the first and second light-emitting diodes are intended to emit visible light in a same wavelength range, preferably blue light.

One embodiment provides a liquid crystal display device comprising:
a backlight and gesture detection device as described; and
in line with the backlight and gesture detection device, a liquid crystal matrix on either side of which are located polarizers.

One embodiment provides a method for manufacturing a backlight and gesture detection device comprising a step of forming, on a same substrate:
first elements for emitting white light;
second elements for emitting infrared radiation or visible light; and
third elements for detecting infrared radiation or visible light emitted by the second elements.

According to one embodiment, the method further comprises a step of forming first and second light-emitting diodes of the first and second elements from a same active light-emitting diode stack.

According to one embodiment, the method further comprises a step of forming first color converters, in line with the first light-emitting diodes, and second visible-to-infrared converters in line with the second light-emitting diodes.

According to one embodiment, the method further comprises a step of transferring, on the first and second light-emitting diodes, a film comprising:
first color converters, intended to be placed in line with the first light-emitting diodes;
second visible-to-infrared converters, intended to be placed in line with the second light-emitting diodes; and
active stacks of infrared photodetectors of the third elements, intended to be placed in line with connection pads of the third elements.

### BRIEF DESCRIPTION OF THE DRAWINGS

The foregoing features and advantages, as well as others, will be described in detail in the following description of particular embodiments given on a non-limiting basis with reference to the accompanying drawings, in which:

FIG. 1A, FIG. 1B, FIG. 1C, FIG. 1D, FIG. 1E, FIG. 1F, FIG. 1G, FIG. 1H and FIG. 1I illustrate, by schematic and partial side and cross-sectional views, successive steps of a method for manufacturing a backlight and gesture detection device according to one embodiment;

FIG. 2A and FIG. 2B illustrate, by schematic and partial side and cross-sectional views, successive steps of a variant of the method for manufacturing the backlight and gesture detection device of FIGS. 1A to 1I; and

FIG. 3 illustrates, schematically and partially, an example of integration of the backlight and gesture detection device of FIGS. 1A to 1I into a liquid crystal display device.

### DESCRIPTION OF THE EMBODIMENTS

The same elements have been designated by the same references in the various Figures. In particular, the structural and/or functional elements common to the various embodiments may have the same references and may have identical structural, dimensional and material properties.

For the sake of clarity, only the steps and the elements useful for understanding the described embodiments have been illustrated and are detailed. In particular, the various applications of the backlight and gesture detection devices of the present description, especially the various electronic devices capable of integrating such devices, have not been detailed, as the described embodiments are compatible with all or most of the usual applications and with all or most of the usual electronic devices implementing a backlight device of the type of those described, for example liquid crystal display screens, possibly with adaptations within the reach of those skilled in the art upon reading the present description.

Furthermore, the implementation of the control circuits of the backlight and gesture detection devices has not been detailed, as the described embodiments are compatible with the usual structures and methods for manufacturing such integrated control circuits.

Unless otherwise specified, when reference is made to two elements connected to each other, this means directly connected without any intermediate elements other than conductors, and when reference is made to two elements coupled to each other, this means that these two elements may be connected or coupled through one or more other elements.

In the following description, when reference is made to absolute position qualifiers, such as the terms “front”, “rear”, “top”, “bottom”, “left”, “right”, etc., or to relative position qualifiers such as the terms “above”, “below”, “upper”, “lower”, etc., or to orientation qualifiers such as the terms “horizontal”, “vertical”, etc., reference is made, unless otherwise specified, to the orientation of the Figures.

Unless otherwise specified, the terms or expressions “about”, “approximately”, “significantly” and “of the order of” mean within 10% or 10°, preferably within 5% or 5°.

Unless otherwise specified, the terms “insulating” and “conductive” respectively mean electrically insulating and electrically conductive.

Unless otherwise specified, the expression “in contact with” means “in mechanical contact with.”

The expression “visible light” refers to an electromagnetic radiation whose wavelength is between 400 nm and 700 nm.

The expression “infrared radiation” refers to an electromagnetic radiation whose wavelength is between 700 nm and 1 mm. In the infrared domain, the near-infrared radiation has a wavelength between 700 nm and 1.7μm.

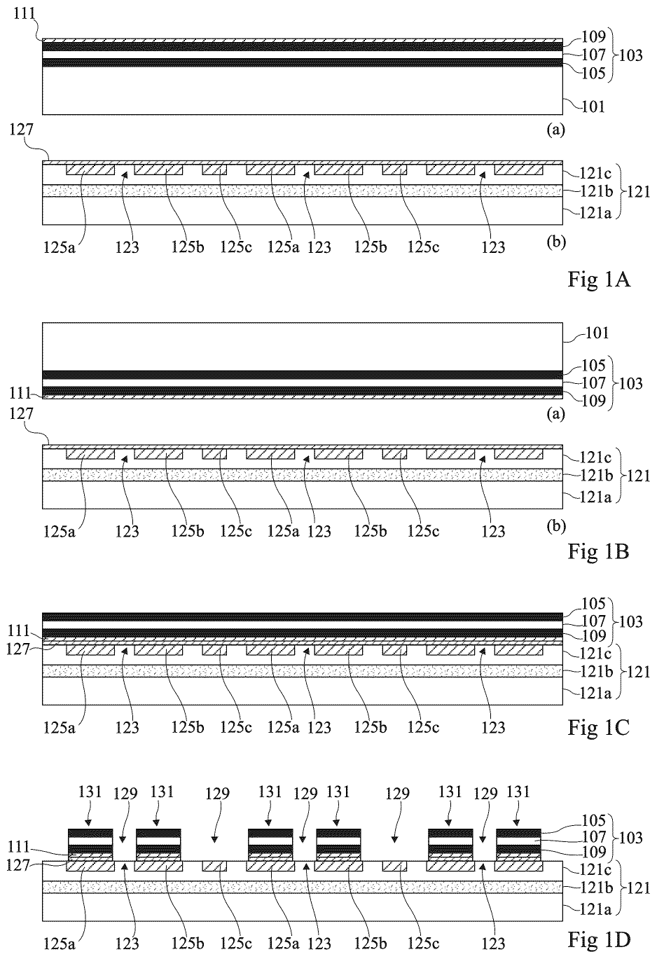

FIG. 1A, FIG. 1B, FIG. 1C, FIG. 1D, FIG. 1E, FIG. 1F, FIG. 1G, FIG. 1H and FIG. 1I illustrate, by schematic and partial side and cross-sectional views, successive steps of a method for manufacturing a backlight and gesture detection device 100 according to one embodiment.

FIG. 1A comprises a view (a) illustrating, in a very schematic manner, a structure comprising a first substrate 101, on the upper surface of which rests an active stack of light-emitting diodes (LEDs) 103. The active stack of LEDs 103 is, for example, a stack of inorganic LEDs, for example based on one or more III-V type semiconductor materials, for example based on gallium nitride. The substrate 101 is, for example, made of sapphire or of silicon.

The active stack of LEDs 103 comprises, for example, in order from the upper surface of the substrate 101, an N-type doped semiconductor layer 105 forming a cathode layer, an active layer 107 and a P-type doped semiconductor layer 109 forming an anode layer. The active layer 107 comprises, for example, alternating layers consisting of layers of quantum wells, or of quantum dots, made of a first semiconductor material, and of barrier layers made of a second semiconductor material defining a stack of multiple quantum wells. Although not illustrated in detail in FIG. 1A, the active stack of LEDs 103 may further comprise one or more other layers, for example selected from injection layers, charge (electrons or holes) transport or blocking layers, buffer layers, etc.

The active stack of LEDs 103 may be formed by epitaxy on the upper surface of the substrate 101. As a variant, the active stack of LEDs 103 is formed by epitaxy on a growth substrate, not illustrated, and then is transferred on the upper surface of the substrate 101.

At this stage, the stack 103 is not yet structured into individual LEDs. In other words, the layers of the stack 103 each extend continuously and with a substantially uniform thickness over the entire upper surface of the substrate 101.

In the illustrated example, the upper surface of the structure of the view (a) is coated with a metallic layer 111 on and in contact with the upper surface of the active stack of LEDs 103. The metallic layer 111 may be a single layer or a stack of several metallic layers. As an example, it is possible to provide a first metallic layer serving as an ohmic contact with the P-type doped semiconductor layer 109 and other overlying metallic layers may serve as reflectors or bonding layers.

FIG. 1A also comprises a view (b) schematically illustrating a control structure comprising a second substrate 121 in and on which a plurality of elementary integrated control circuits 123, for example identical or similar, have been formed, respectively corresponding to integrated control circuits of future elementary chips of the device 100.

The substrate 121 may have a monoblock structure, or may correspond to a layer covering a support made of another material. The substrate 121 is, for example, made of a semiconductor material, for example of silicon. As an example, the substrate 121 is a wafer or a piece of wafer made of monocrystalline silicon, the upper surface of the substrate 121 having, for example, a crystalline orientation <111>. In the illustrated example, the substrate 121 has a multilayer structure of the silicon-on-insulator type, also called “Semiconductor On Insulator SOI”, comprising a semiconductor support substrate 121a, for example made of silicon, an insulating layer 121b, for example made of silicon oxide, disposed on and in contact with the upper surface of the support substrate, and an upper semiconductor layer 121c, for example made of monocrystalline silicon, disposed on and in contact with the upper surface of the insulating layer 121b.

In the illustrated example where the substrate 121 is of the SOI type, the elementary control circuits 123 are, for example, formed in and on the upper semiconductor layer 121c of the substrate 121. Each elementary control circuit 123 comprises, for example, a plurality of MOS transistors (not detailed on FIGS. 1A to 1I). The elementary control circuits 123 are, for example, made using CMOS (Complementary Metal Oxide Semiconductor) technology.

In this example, each elementary control circuit 123 comprises, on the side of its upper surface, one or more connection metallic pads 125a, 125b, 125c. As an example, the pads 125a, 125b, 125c are flush on the side of the upper surface of an upper insulating layer, for example made of silicon oxide, of an interconnection stack (not detailed on the Figures) coating the upper surface of the upper semiconductor layer 121c of the substrate 121. Thus, in this example, the upper surface of the control structure of the view (b) is a flat surface comprising an alternation of metallic regions (the pads 125a, 125b, 125c) and of insulating regions.

As an example, each elementary control circuit 123 comprises a metallic pad 125a specific for a white light-emitting element, or white light source, of the future elementary chip of the device 100, to be connected to an anode region of the white light-emitting element and making it possible to individually control the light emission by this element. In this example, each elementary control circuit 123 further comprises a metallic pad 125b specific for an infrared (IR) emitting element, or infrared source, of the future elementary chip of the device 100, to be connected to an anode region of the IR-emitting element and making it possible to individually control the light emission by this element. Each elementary control circuit 123 further comprises a metallic pad 125c specific for an infrared detecting element, or infrared capture element, of the future elementary chip of the device 100, to be connected to an anode region of the IR-detecting element and making it possible to collect photo-generated charges by this element.

Furthermore, although this has not been illustrated in FIGS. 1A to 1I in order not to overload the drawing, each elementary control circuit 123 may additionally comprise one or more metallic pads to be connected to one or more cathode regions of one or more elements among the white light-emitting element, the IR-emitting element and the IR-detecting element. As an example, the control circuit 123 comprises a single metallic pad to be connected collectively to the cathode regions of the white light-emitting element, of the IR-emitting element and of the IR-detecting element. As a variant, the control circuit 123 comprises a first metallic pad to be connected to the cathode region of the white light-emitting element and a second metallic pad to be connected to the cathode regions of the IR-emitting element and of the IR-detecting element, or the first and second metallic pads are respectively connected to the cathode regions of the white light-emitting element and of the IR-emitting element and to the cathode region of the IR-detecting element.

Each elementary control circuit 123 may comprise a circuit adapted to control the emission of white light by the white light-emitting element, another circuit adapted to control the emission of infrared radiation by the IR-emitting element and yet another circuit adapted to control the detection of infrared radiation by the IR-detecting element.

In the illustrated example, the upper surface of the control structure of the view (b) is coated with a metallic layer 127. In this example, the layer 127 extends continuously and with a substantially uniform thickness over the entire upper surface of the interconnection stack of the control structure. Thus, the layer 127 connects to each other all the metallic pads 125a, 125b, 125c of the control structure. This makes it possible to perform a subsequent bonding step without alignment, the metallic pads 125a, 125b, 125c then being electrically separated during an etching step. The metallic layer 127 may be a single layer or a stack of several metallic layers. Preferably, the metallic layer 127 comprises, on the side of its upper surface, a layer of the same material as the layer 111.

FIG. 1B comprises a view (a) illustrating in a very schematic manner the structure of the view (a) of FIG. 1A, which has been flipped with respect to the orientation of FIG. 1A. This operation corresponds, for example, to a step prior to transferring the structure of the view (a) of FIG. 1A on the upper surface of the structure of the view (b) of FIG. 1A, reproduced in the view (b) of FIG. 1B, using the substrate 101 as a handle.

FIG. 1C illustrates the structure obtained after a subsequent step of transferring and fixing the active stack of LEDs 103 and the metallic layer 111 on the structure of the view (b) of FIG. 1B.

During this step, the lower surface (in the orientation of FIG. 1B, corresponding to the upper surface in the orientation of FIG. 1A) of the metallic layer 111 is fixed on the upper surface of the metallic layer 127. The fixation is achieved, for example, by direct bonding or by molecular bonding of the lower surface of the layer 111 on the upper surface of the layer 127, i.e. without added material between the two layers.

The substrate 101 is then removed, for example by grinding and/or chemical etching, so as to provide access to the upper surface of the active stack of LEDs 103, i.e. in this example, the upper surface of the cathode semiconductor layer 105 of the active stack of LEDs 103. As a variant, the removal of the substrate 101 may be performed by laser lift-off, for example in the case where the substrate 101 is made of sapphire.

FIG. 1D illustrates a step of forming trenches 129 extending vertically into the active stack of LEDs 103 from its upper surface and laterally delimiting, in the stack 103, a plurality of islands 131 corresponding to individual LEDs of the future elementary chips of the device. The trenches 129 are formed, for example, by plasma etching. In a top view (not illustrated), the trenches 129 form a grid laterally separating the islands 131 from each other.

FIG. 1D further illustrates a subsequent step of vertically extending the trenches 129 through the metallic layers 111 and 127, for example using the same etching mask (not illustrated) as that used in the previous step. At the end of this step, the trenches 129 open onto the upper surface of the interconnection stack coating the upper surface of the substrate 121.

The portion of the stack of layers 111 and 127 remaining under each LED 131 at the end of this step constitutes an anode electrode of the LED. Said anode electrode is in contact, by its underside, with the upper surface of a connection metallic pad 125a or 125b of the underlying elementary control circuit 123. Thus, each LED 131 has its anode electrode individually connected to a connection metallic pad 125a of an elementary control circuit 123.

In this example, a trench 129 is also formed opposite each connection metallic pad 125c so as to provide access to the upper surface of the pads 125c. Furthermore, although this has not been illustrated, a trench 129 is for example also formed opposite each cathode connection metallic pad so as to provide access to its upper surface. As a variant, the contact can be made on the rear surface by means of conductive through-vias, for example of the TSV (Through-Silicon Via) type, after thinning the substrate 121.

FIG. 1E illustrates a subsequent step of passivating the sides of the LEDs 131. For this purpose, a layer 133 made of an electrically insulating material, for example of silicon oxide or of silicon nitride, is deposited by a conformal deposition method on the upper surface of the structure. The layer 133 then coats the upper surface and the sides of the LEDs 131 as well as the sides of the portions of the metallic layers 111 and 127 located under the LEDs 131 and, at the bottom of the trenches 129, the upper surface of the interconnection stack coating the substrate 121. A vertical anisotropic etching step is then performed to remove the horizontal portions of the layer 133 and to retain only the vertical portions of this layer, coating the sides of the LEDs 131 and the sides of the portions of the metallic layers 111 and 127 located under the LEDs 131.

FIG. 1E further illustrates a subsequent step of filling the trenches 129 with an insulating material 135. As an example, the insulating material 135 is initially deposited over the entire upper surface of the structure with a thickness greater than the depth of the trenches 129, so as to completely fill the trenches 129. A planarization step, for example by chemical mechanical polishing, is then performed to provide access to the upper surface of the LEDs 131. Thus, this results in a substantially flat upper surface on which the cathode semiconductor regions 105 of the LEDs 131 and the insulating regions 135 filling the trenches 129 are flush. Viewed from above (not illustrated), the insulating regions 135 form an insulating grid that laterally separates the LEDs 131 from each other. As an example, the insulating regions 135 are made of a polymer material or, more generally, of any type of material used to form a planarization layer.

FIG. 1F illustrates a subsequent step of forming trenches extending vertically into the insulating regions 135 in line with the connection metallic pads 125c. More specifically, the trenches extend from the upper surface of the insulating regions 135 and open onto the upper surface of the connection metallic pads 125c.

FIG. 1F further illustrates a subsequent step of filling the trenches formed in the insulating regions 135 with a photodetector active stack 137. The photodetector active stack 137 comprises, for example, in order from the upper surface of the substrate 121, a P-type doped semiconductor layer forming an anode layer, an active layer and an N-type doped semiconductor layer forming a cathode layer. The photodetector active stack is, for example, made from inorganic materials, the active layer comprising, for example, a plurality of quantum wells or dots, or from organic materials. The active layer is, for example, a layer comprising quantum dots in a polymer matrix. In the case of organic materials, the photodetector active stack 137 can be made by spin-coating. In the illustrated example, the side surfaces of each photodetector 137 are coated with the insulating material 135, the material 135 being, for example, located on and in contact with all the side surfaces of the photodetector 137. Although not detailed, a stack of one or more hole injection and/or transport layers (not illustrated) may be deposited on the bottom of the trenches prior to depositing of the active layer.

FIG. 1F further illustrates a subsequent step of depositing, on the upper surface of the structure, a conductive layer 139 that is transparent to the emission wavelengths of the LEDs and to the detection wavelengths of the photodetectors of the device. The layer 139 extends, for example, continuously and with a substantially uniform thickness over the entire upper surface of the structure. The layer 139 is, for example, made of a transparent conductive oxide, for example of indium tin oxide (ITO). As a variant, the layer 139 may be a metallic layer that is sufficiently thin to be transparent, for example a silver layer of a thickness less than 80 nm.

The layer 139 is in contact, via its lower surface, with the upper surface of the cathode semiconductor regions 105 of the LEDs 131 and with the upper surface of the photodetectors 137. The layer 139 connects, for example electrically, the cathode semiconductor region 105 of each LED 131 and the cathode layer of each photodetector 137 to a common cathode contact metallization of the structure (not illustrated). However, based on the information provided in this description, those skilled in the art would be able to foresee layers similar to the layer 139 that would be isolated from each other and connected to different cathode contact metallizations.

FIG. 1G illustrates a subsequent step of forming color converters 141a in line with the LEDs 131 located in contact with the metallic pads 125a and visible-to-infrared converters 141b in line with the LEDs 131 located in contact with the metallic pads 125b.

As an example, the LEDs 131 are designed to emit blue light. In this case, each converter 141a is configured, for example, to convert the blue light emitted by the underlying LED 131 into white light and each converter 141b is configured, for example, to convert the blue light emitted by the underlying LED 131 into IR radiation. In the case where the LEDs 131 emit blue light, the converters 141a are, for example, white converters comprising a mixture of materials respectively allowing a conversion of the blue light into red light and into green light while allowing part of the blue light to pass through. Each converter 141a is thus configured to transmit, from the blue light emitted by the underlying LED 131, white light formed from green, red and blue light.

The converters 141a and 141b are, for example, made from phosphors, quantum dots, thin layers made of perovskite material, etc. As an example, the converters 141a and 141b are formed by successive deposits.

Although not illustrated in FIG. 1G, opaque barriers may be provided between the converters to prevent crosstalk phenomena. In this case, an opaque layer, for example a layer of black resin, is for example deposited over the entire upper surface of the conductive layer 139 and the converters 141a and 141b are for example made in cavities previously formed in the opaque layer.

FIG. 1G also illustrates a step of forming micro-lenses 143 in line with the LEDs 131 and the photodetectors 137.

In the illustrated example, the micro-lens 143 located in line with each LED 131 is disposed on and in contact with the upper surface of the converter 141a, 141b associated with the LED 131. Furthermore, in this example, the micro-lens 143 located in line with each photodetector 137 is disposed on and in contact with the upper surface of the conductive layer 139.

As an example, the micro-lenses 143 can be formed by photolithography followed by etching. As a variant, the micro-lenses 143 may be disposed on a support, for example a film, placed on the side of the upper surface of the structure. Although FIG. 1G illustrates an example embodiment using micro-lenses 143, any type of optical component to focus, or to format, a beam may be used as a variant.

In the illustrated example, the structure of FIG. 1G comprises:
white light-emitting elements 145a, each comprising the LED 131, the converter 141a and the micro-lens 143 located in line with one of the metallic pads 125a;
infrared radiation emitting elements 145b, or infrared emitting elements 145b, each comprising the LED, the converter 141b and the micro-lens 143 located in line with one of the metallic pads 125b; and
   infrared radiation detecting elements 145c, to detect the infrared radiation emitted by the elements 145b, each comprising the photodetector 137 and the micro-lens 143 located in line with one of the metallic pads 125c.

The elements 145a, 145b and 145c are, as in the illustrated example in FIG. 1G, substantially coplanar. In the illustrated example, the LEDs 131 of the white light-emitting elements 145a and the LEDs 131 of the IR-emitting elements 145b are designed to emit visible light in a same wavelength range.

The method above described in relation to FIGS. 1A to 1G can be used to produce a monolithic backlight and gesture detection device. FIGS. 1H and 1I described below are, for example, implemented following the steps of FIGS. 1A to 1G in a case where a larger backlight and gesture detection device is desired.

FIG. 1H illustrates a step of forming trenches 147 laterally delimiting a plurality of semiconductor chips 149 corresponding to elementary chips of the backlight and gesture detection device 100. In the illustrated example, the trenches 147 extend vertically in the structure from the upper surface of the conductive layer 139 to the lower surface of the substrate 121. The trenches 147 may be formed by plasma etching, by sawing or by any other suitable cutting method.

As an example, a temporary support substrate (not illustrated), such as a film, may be used to mechanically hold the elementary chips 149 during and after the cutting operation.

FIG. 1I illustrates a subsequent step of fixing elementary chips 149 to the upper surface of a same transfer substrate 151, for example a glass substrate, of the backlight and gesture detection device 100. The transfer substrate 151 is, for example, a control substrate for the elementary chips 149. The transfer substrate 151 comprises, for example, on the side of its upper surface, a plurality of connection metallic pads (not illustrated) to be fixed and electrically and mechanically connected to corresponding connection metallic pads (not illustrated) of the elementary chips 149. The elementary chips 149 are, for example, disposed on the transfer substrate 151 so as to place the connection metallic pads of the elementary chips 149 opposite corresponding connection metallic pads of the transfer substrate 151. The pads opposite to each other are then fixed and electrically connected, for example by direct bonding, by soldering, using micro-tubes or by any other suitable method. The elements 145a, 145b and 145c are thus electrically connected to the substrate 151. Although this has not been detailed in FIG. 1I so as not to overload the drawing, the substrate 151 comprises, for example, conductive tracks, for example organized in rows and columns for coupling the connection metallic pads.

In a case where a temporary support substrate is used, the elementary chips 149 are, once fixed to the transfer substrate 151, detached from the temporary support substrate, and the latter is removed. Thus, this results in a simultaneous collective transfer of a plurality of elementary chips 149 from the temporary support substrate to the transfer substrate 151. The pitch, i.e. the center-to-center distance in a front view, of the elementary chips 149 on the transfer substrate 151 is, for example, a multiple of the pitch of the elementary chips 149 on the temporary support substrate. Thus, only a portion of the elementary chips are simultaneously transferred from the temporary support substrate to the transfer substrate 151. The other chips remain fixed on the temporary support substrate and can be transferred later to another portion of the transfer substrate 151 or to another transfer substrate.

As a variant, elementary chips 149 can be disposed successively on the transfer substrate 151 by a so-called “pick-and-place” robot.

The above describes an example embodiment in which each elementary chip 149 comprises a stack of an integrated control circuit, for example a CMOS circuit, and a white light-emitting element 145a, an IR-emitting element 145b and an IR-detecting element 145c.

As a variant, each elementary chip 149 may comprise one or more elements among the elements 145a, 145b and 145c, the other elements then forming part of one or more other elementary chips analogous to the elementary chip 149. As an example, first elementary chips each comprise a white light-emitting element 145a and an IR-emitting element 145b and second elementary chips each comprise an IR-detecting element 145c, the control circuits 123 for the elements 145a, 145b and 145c being, for example, integrated into the first element chips. This makes it possible, for example, to make the photodetectors 137 of the IR-detecting elements 145c from indium gallium arsenide (InGaAs). As a variant, the first elementary chips may each comprise only the white light-emitting element 145a, the second elementary chips then each comprising an IR-emitting element 145b and an IR-detecting element 145c, the control circuits 123 for the elements 145a, 145b and 145c being, for example, integrated into the first elementary chips. In this variant, the device 100 may comprise equal or different numbers of first and second elementary chips. As an example, the device 100 may comprise more first chips comprising the element 145a than second chips comprising the elements 145b and 145c.

Although only four elementary chips 149 have been illustrated in FIG. 1I for the sake of simplicity, the device 100 may of course comprise a greater number of elementary chips 149 than that illustrated, for example several hundred or several thousand elementary chips 149.

Furthermore, although this has not been detailed in the Figures, the elementary integrated control circuits 123 of the elementary chips 149 may also be used to control elements external to the elementary chips, for example selected among electromechanical transducers, optoelectronic transducers, thermoelectric transducers, energy capture elements, energy storage elements, etc.

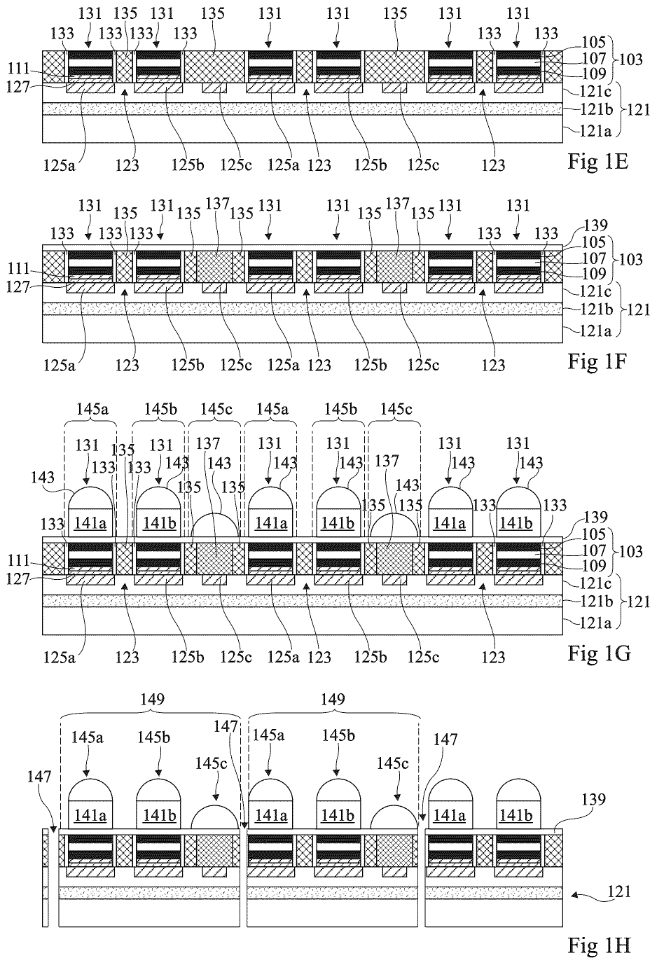

FIG. 2A and FIG. 2B illustrate, by schematic and partial side and cross-sectional views, successive steps of a variant of the method for manufacturing the backlight and gesture detection device 100 of FIGS. 1A to 1I.

FIG. 2A illustrates a step of transferring elementary chips 249 on the upper surface of the transfer substrate 151. The elementary chips 249 are, for example, similar to the elementary chips 149, but without the converters 141a, 141b and the photodetectors 137. Like the elementary chips 149, each elementary chip 249 comprises the two LEDs 131 located on the upper surface of portions of the substrate 121 that remain after a cutting step for example analogous to that previously described in relation to FIG. 1H.

FIG. 2B illustrates a step of transferring, on the side of the upper surface of the structure, a support 251, for example a film, integrating, for each elementary chip 249, the converters 141a, 141b and the photodetector 137. As soon as the support 251 has been transferred on the elementary chips 249, the converters 141a, 141b and the photodetectors 137 are respectively located in line with the LEDs 131 and the connection metallic pads 125c.

FIG. 2B further illustrates a step of forming or transferring the micro-lenses 143 in line with the converters 141a, 141b and the photodetectors 137. The micro-lenses 143 are for example carried by the support 251. As a variant, the micro-lenses 143 may be disposed on a support, for example a film, placed on the side of the upper surface of the structure, for example on and in contact with the support 251, or the micro-lenses 143 are formed on the support 251 by photolithography and then etching.

At the end of these steps, a backlight and gesture detection device 200 similar to the device 100 is obtained.

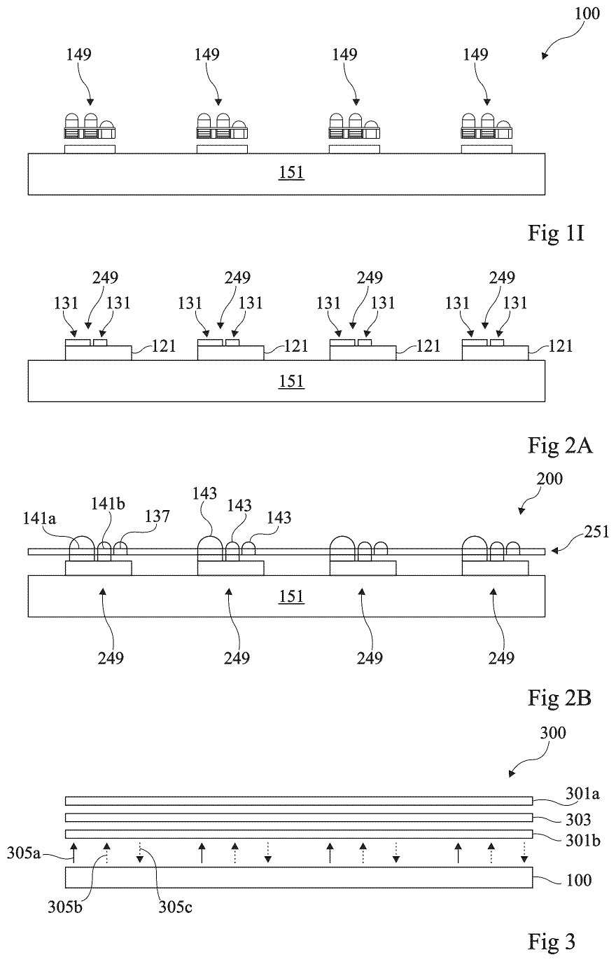

FIG. 3 illustrates, schematically and partially, an example of integration of the backlight and gesture detection device of FIGS. 1A to 1I into a liquid crystal display device 300.

In the illustrated example, the device 300 comprises two polarizers 301a and 301b, for example crossed linear polarizers, disposed on either side of a liquid crystal matrix 303 and located in line with the backlight and gesture detection device 100. Each of the elementary chips 149 of the device 100 (not illustrated in detail in FIG. 3) emits white light (arrow 305a) and infrared radiation (arrow 305b) toward the liquid crystal matrix 303 and receives infrared radiation (arrow 305c) from an external environment located above the liquid crystal matrix 303, in the orientation of FIG. 3. The visible light emitted by the white light-emitting elements 145a makes it possible to implement a backlight function for the liquid crystal matrix 303, for example in a manner analogous to a so-called “backlit” device. In addition, the IR radiation emitted and captured respectively by the IR-emitting elements 145b and by IR-detecting elements 145c makes it possible, for example, to implement a gesture detection function. The implementation of the gesture detection function is within the reach of those skilled in the art based on the indications in the present description.

As a variant, the device 100 could be replaced by the device 200 in the liquid crystal display device 300.

One advantage of the devices 100 and 200 is that they make it possible to combine, by means of components formed on a same substrate, backlight and gesture detection functions. This makes it possible, for example, that the device 300 integrating the device 100 or 200 has a smaller footprint than if the backlight and gesture detection functions were performed by components formed on distinct substrates.

Furthermore, the fact that the LEDs 131 of the white light-emitting elements 145a and the LEDs 131 of the IR-emitting elements 145b are made from the same active stack of LEDs 103 advantageously simplifies the manufacture of the devices 100 and 200. The manufacture of the devices 100 and 200 is further facilitated by the integration of the control circuits 123 into the chips 149, which advantageously eliminates the need for an active array.

Various embodiments and variants have been described. Those skilled in the art will understand that certain features of these various embodiments and variants could be combined, and other variants will be apparent to those skilled in the art. In particular, although the present description takes as an example a case in which the LEDs 131 are to emit blue light, this example is not limiting, and those skilled in the art are able, based on the present description, to adapt the embodiments described to a case in which the LEDs 131 emit visible light other than blue light.

Furthermore, those skilled in the art are able, based on the information in the present description, to transpose what has been described taking as an example a case where the gesture detection is implemented based on the emission and the detection of infrared radiation to a case where the gesture detection is performed based on the emission and the detection of visible light, the elements 145b then being visible light-emitting elements and the elements 145c being visible light detecting elements, to detect the visible light emitted by the elements 145b. In this case, the visible-to-infrared converters 141b are for example omitted and the photodetector active stacks 137 of the elements 145c are for example visible photodetector active stacks.

Finally, the practical implementation of the described embodiments and variants is within the reach of those skilled in the art based on the functional indications given above. In particular, the described embodiments are not limited to the specific examples of materials and dimensions mentioned in the present description.

What is claimed is:

1. A backlight and gesture detection device comprising:
first elements for emitting white light;
second elements for emitting infrared radiation or visible light; and
third elements for detecting infrared radiation or visible light emitted by the second elements,
wherein the first, second and third elements are electrically connected to a same substrate,
the device comprising a plurality of elementary chips, each comprising one or more elements among one of the first elements, one of the second elements and one of the third elements.

2. The device according to claim 1, wherein the elementary chips each comprise one of the first elements, one of the second elements and one of the third elements.

3. The device according to claim 2, wherein each elementary chip further comprises an elementary circuit for controlling the first, second and third elements.

4. The device according to claim 1, comprising:
a plurality of first elementary chips, each comprising one of the first elements and one of the second elements; and
a plurality of second elementary chips, each comprising one of the third elements.

5. The device according to claim 4, wherein each first elementary chip further comprises an elementary circuit for controlling the first, second and third elements.

6. The device according to claim 4, wherein each third element is an infrared photodetector based on indium gallium arsenide.

7. The device according to claim 1, comprising:
a plurality of first elementary chips, each comprising one of the first elements; and
a plurality of second elementary chips, each comprising one of the second elements and one of the third elements.

8. The device according to claim 7, wherein each first elementary chip further comprises an elementary circuit for controlling the first, second and third elements.

9. The device according to claim 1, wherein each first element comprises a first light-emitting diode topped with a first color converter.

10. The device according to claim 1, wherein each second element comprises a second light-emitting diode topped with a second visible-to-infrared converter.

11. The device according to claim 9, wherein the first and second light-emitting diodes are intended to emit visible light in a same wavelength range, preferably blue light.

12. A liquid crystal display device comprising:
a backlight and gesture detection device according to claim 1; and
in line with the backlight and gesture detection device, a liquid crystal matrix on either side of which are located polarizers.

13. A method for manufacturing a backlight and gesture detection device comprising a step of forming, on a same substrate:
first elements for emitting white light;
second elements for emitting infrared radiation or visible light; and
third elements for detecting infrared radiation or visible light emitted by the second elements,
the device comprising a plurality of elementary chips, each comprising one or more elements among one of the first elements, one of the second elements and one of the third elements.

14. The method according to claim 13, further comprising a step of forming first and second light-emitting diodes of the first and second elements from a same active light-emitting diode stack.

15. The method according to claim 14, further comprising a step of forming first color converters, in line with the first light-emitting diodes, and second visible-to-infrared converters in line with the second light-emitting diodes.

16. The method according to claim 14, further comprising a step of transferring, on the first and second light-emitting diodes, a film comprising:
first color converters, intended to be placed in line with the first light-emitting diodes;
second visible-to-infrared converters, intended to be placed in line with the second light-emitting diodes; and
active stacks of infrared photodetectors of the third elements, intended to be placed in line with connection pads of the third elements.
